(19) United States
(12) Patent Application Publication
(10) Pub. No.: US 2013/0156226 A1
(43) Pub. Date: Jun. 20, 2013

(54) VOLUME ADJUSTMENT CIRCUIT WITH AUTOMATIC GAIN CONTROL AND ELECTRONIC DEVICE USING SAME

(71) Applicants: REN-WEN HUANG, Shenzhen City (CN); ZONG-XIAO LUO, Shenzhen City (CN); JUN ZHANG, Shenzhen City (CN); TSUNG-JEN CHUANG, Tu-Cheng (TW)

(72) Inventors: REN-WEN HUANG, Shenzhen City (CN); ZONG-XIAO LUO, Shenzhen City (CN); JUN ZHANG, Shenzhen City (CN); TSUNG-JEN CHUANG, Tu-Cheng (TW)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/480,484

(22) Filed: May 25, 2012

(30) Foreign Application Priority Data
Dec. 16, 2011 (CN) 201110423291.1

(51) Int. Cl. H03G 3/20

(52) U.S. Cl. 381/107; 330/127

(57) ABSTRACT

A volume adjustment circuit includes an amplification circuit, a control circuit and an adjustment circuit. The amplification circuit amplifies a first audio signal received and generates a second audio signal, and outputs the second audio signal to an audio output terminal. The control circuit is electrically coupled to the audio output terminal, and is configured to generate a control signal based on the second audio signal. The adjustment circuit is electrically coupled to the control circuit, and configured to adjust an amplitude of the first audio signal inputted to the amplification circuit based on the control signal.

### BACKGROUND

1. Technical Field

The present disclosure relates to volume adjustment technology, and more particular, to a volume adjustment circuit with automatic gain control and an electronic device using the volume adjustment circuit.

2. Description of Related Art

Electronic devices, such as mobile phones, portable media players, and computer displays with speakers, usually have a volume adjustment circuit for adjusting an audio volume thereof. Most volume adjustment circuit uses a fixed amplification coefficient for amplifying an audio signal. Assuming the amplification coefficient is β, when an input audio signal having an original volume value K is received by the volume adjustment circuit, the volume adjustment circuit amplifies the audio signal β times, and consequently, an audible output has an adjusted volume value βK. However, when the original volume value K of the input audio signal is sufficiently great, in practice, only a slight amplification on the input audio signal would be required. The above-mentioned volume adjustment circuit can only perform the volume amplification β times on the input audio signal, this may cause the audible output to be too loud for the user.

What is needed is an volume adjustment circuit that can overcome the above-described limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views, and all the views are schematic.

FIG. 1 is a circuit diagram of a volume adjustment circuit according to an embodiment of the present disclosure.

FIG. 2 is a block diagram of an electronic device using the volume adjustment circuit of FIG. 1.

### DETAILED DESCRIPTION

Reference will be made to the drawings to describe certain exemplary embodiments of the present disclosure.

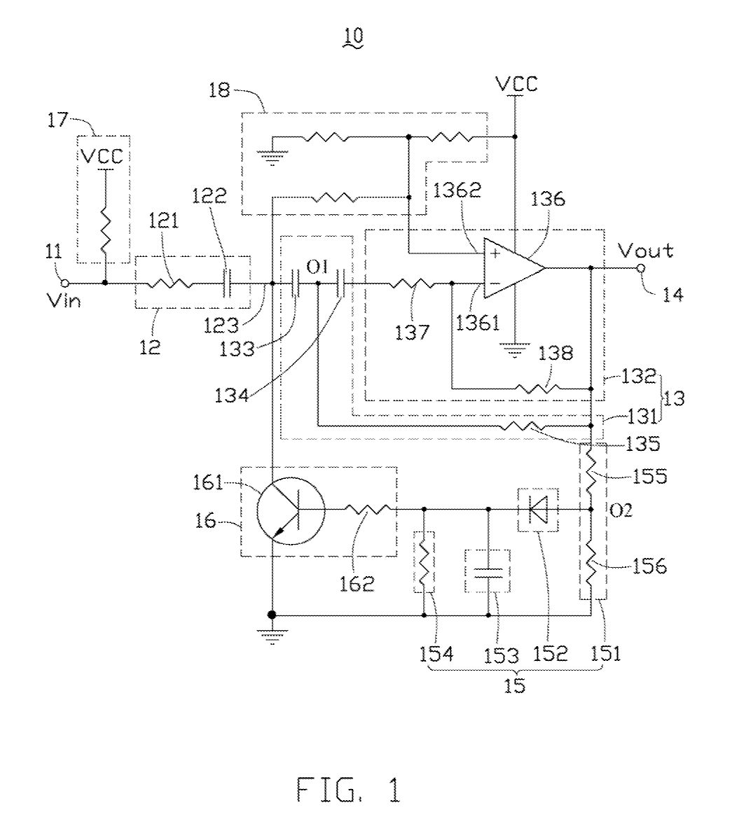

FIG. 1 schematically illustrates a volume adjustment circuit 10 according to an embodiment of the present disclosure. The volume adjustment circuit 10 includes an audio input terminal 11, an amplification circuit 13, a control circuit 15, an adjustment circuit 16 and an audio output terminal 14.

The audio input terminal 11 receives an input audio signal Vin. The audio input terminal 11 may be electrically coupled to the amplification circuit 13 via a first filter circuit 12. The first filter circuit 12 may be a resistor-capacitor (RC) filter circuit used for filtering out a direct current (DC) component from the input audio signal. In one embodiment, the first filter circuit 12 includes a first current limiting resistor 121, a filter capacitor 122 and an output terminal 123. One end of the first current limiting resistor 121 is electrically coupled to the audio input terminal 11, and also coupled to a DC voltage VCC via a pull-up resistor 17; the other end of the first current limiting resistor 121 is electrically coupled to the output terminal 123 of the first filter circuit 12 via the filter capacitor 122.

The amplification circuit 13 includes a second filter circuit 131 and an operational amplifier circuit 132. The second filter circuit 131 may include a second filter capacitor 133, a third filter capacitor 134, and a resistor 135. The second filter capacitor 133 and the third filter capacitor 134 are electrically coupled in series between the output terminal 123 of the first filter circuit 12 and the operational amplifier circuit 132, and the resistor 135 may be a variable resistor that is used for providing an additional amplification coefficient modification function for the amplification circuit 13. One end of the resistor 135 is electrically coupled to a node O1 between the second filter capacitor 133 and the third filter capacitor 134, and the other end of the resistor 135 is electrically coupled to the audio output terminal 14. Alternatively, in one embodiment, the second filter circuit 131 can only include the second filter capacitor 133, that is, the third filter capacitor 134 and the resistor 135 may be removed from the second filter circuit 131.

The operational amplifier circuit 132 includes an operational amplifier (OA) 136, a first bias resistor 137 and a second bias resistor 138. The OA 136 includes a reversed-phase input 1361 and an in-phase input 1362. The reversed-phase input 1361 of the OA 136 is electrically coupled to the second filter circuit 131 via the first bias resistor 137, and is electrically coupled to the audio output terminal 14 via the second bias resistor 138. The in-phase input 1362 of the OA 136 is electrically coupled to a reference voltage generating circuit 18, and receives a reference voltage from the reference voltage generating circuit 18. Moreover, an output of the OA 136 is also electrically coupled to the audio output terminal 14. In one embodiment, the reference voltage generating circuit 18 may be coupled to the DC voltage VCC, and is configured to convert the DC voltage VCC into the reference voltage.

The control circuit 15 includes a voltage divider 151 to carry out a voltage division on an output audio signal Vout to form a control signal. For example, the voltage divider 151 may include a first voltage dividing resistor 155 and a second voltage dividing resistor 156 electrically coupled in series between the audio output terminal 14 and ground, and a node O2 between the first voltage dividing resistor 155 and the second voltage dividing resistor 156 may serve as an output terminal of the voltage divider 151 and for outputting the control signal to the adjustment circuit 16.

The control circuit 15 may further include a rectifying circuit 152, a filter branch 153, and a discharge branch 154. The rectifying circuit 152 is used for rectifying the control signal from the voltage divider 151, for example, the rectifying circuit 152 may be a diode with an anode electrically coupled to the node O2 and a cathode electrically coupled to an input terminal of the adjustment circuit 16. The filter branch 153 is electrically coupled between the cathode of the rectifying diode and ground, the filter branch 153 may include at least one capacitor for filtering an alternating current (AC) out from the rectified control signal. The discharge branch 154 is electrically coupled to the filter branch 153 in parallel, the discharge branch 154 may include a discharge resistor for providing a discharge path for the filter capacitor of the filter branch 153.

The adjustment circuit 16 includes a voltage adjusting member 161 and a second current limiting resistor 162. The voltage adjustment member 161 may include a bipolar junction transistor, which adjusts a voltage between a collector electrode and an emitter electrode of the transistor according to an input voltage to a base electrode of the transistor. The base electrode of the transistor is electrically coupled to one end of the second current limiting resistor 162, the other end of the second current limiting resistor 162 serves as the input terminal of the adjustment circuit 16 for receiving the control signal, and is electrically coupled to the cathode of the rectifying diode. The emitter electrode of the transistor may be grounded directly or be grounded via a resistor. The collector electrode of the transistor is electrically coupled to the output terminal 123 of the first filter circuit 12, in another embodiment, the collector electrode of the transistor may alternatively be coupled to the audio input terminal 11.

In operation of the volume adjustment circuit 10, an input audio signal Vin is received by the audio input terminal 11. After being filtered by the first filter circuit 12 and the second filter circuit 131 sequentially to remove undesired DC noise, the audio signal is then inputted to the operational amplifier circuit 132 for volume amplification. In particular, the operational amplifier circuit 132 may amplify the audio signal N times, and then output the amplified audio signal as an output audio signal Vout to the audio output terminal 14. In the present embodiment, with the above-mentioned configuration of operational amplifier circuit 132, an amplification coefficient N is substantially equal to R2/R1, wherein R1 and R2 represent resistances of the first bias resistor 137 and the second bias resistor 138 respectively. As such, the output audio signal Vout of the volume adjustment circuit has an amplitude of about (R2/R1)*Vin. Moreover, the control circuit 15 further coverts the output audio signal Vout into a control signal, and provides the control signal to the adjustment circuit 16.

When an amplitude of the input audio signal Vin decreases, the amplitude of the output audio signal Vout correspondingly decreases, and accordingly, an amplitude of the control signal provided to the adjustment circuit 16 also decreases. The decreasing of the control signal may reduce a conductivity of the voltage adjusting member 161, and thereby pulling up the amplitude of the audio signal inputted to the operational amplifier circuit 132. Therefore, the amplitude of the output audio signal Vout can be maintained to meet an audio listening requirement of a user.

When the amplitude of the input audio signal Vin increases, the amplitude of the output audio signal Vout correspondingly increases, and accordingly, the amplitude of the control signal provided to the adjustment circuit 16 increases. The increasing of the control signal may raise a conductivity of the voltage adjusting member 161, and thereby pulling down the amplitude of the audio signal inputted to the operational amplifier circuit 132. Therefore, the amplitude of the output audio signal Vout is kept down, and this may efficiently prevent an output audio volume from being too loud. As such, the audio user experience of the electronic device using the volume adjustment circuit is improved.

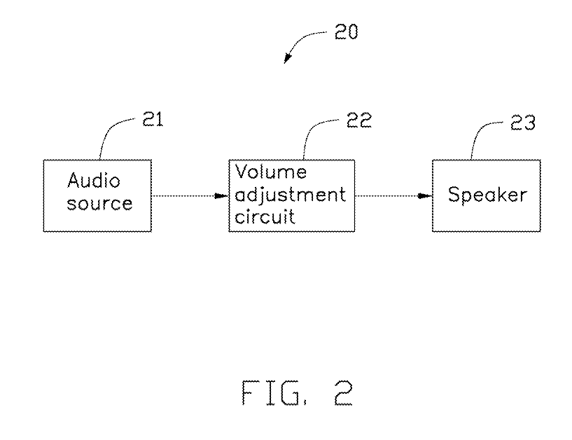

Based on the above volume adjustment circuit, the present disclosure further provides an electronic device using the volume adjustment circuit. Referring to FIG. 2, an electronic device 20 according to an embodiment of the present disclosure includes an audio source 21, a volume adjustment circuit 22 and a speaker 23. The volume adjustment circuit 22 may be the volume adjustment circuit 10 as illustrated in FIG. 1 and as described above. The audio source 21 is electrically coupled to an audio input terminal of the volume adjustment circuit 22, and is configured to provide an input audio signal to the volume adjustment circuit 22. The speaker 23 is electrically coupled to an audio output terminal of the volume adjustment circuit 22, and is configured to transform an output audio signal of the volume adjustment circuit 22 into an audible signal for a user. The details of the volume adjustment of the electronic device 20 are as those of the volume adjustment circuit 10.

It is to be further understood that even though numerous characteristics and advantages of preferred and exemplary embodiments have been set out in the foregoing description, together with details of the structures and functions of the embodiments, the disclosure is illustrative only; and that changes may be made in detail, especially in the matters of shape, size and arrangement of parts within the principles of the present disclosure to the full extent indicated by the broad general meaning of the terms in which the appended claims are expressed.

What is claimed is:

1. A volume adjustment circuit, comprising:
an amplification circuit, configured for amplifying a first audio signal inputted to generate a second audio signal, and outputting the second audio signal to an audio output terminal;
a control circuit electrically coupled to the audio output terminal, the control circuit being configured for generating a control signal based on the second audio signal; and
an adjustment circuit electrically coupled to the control circuit, the adjustment circuit being configured for adjusting an amplitude of the first audio signal inputted to the amplification circuit based on the control signal.

2. The volume adjustment circuit of claim 1, further comprising a first filter circuit electrically coupled between an audio input terminal and the amplification circuit, wherein the first filter circuit is configured for filtering out a direct current component from an input audio signal received by the audio input terminal to form the first audio signal inputted to the amplification circuit.

3. The volume adjustment circuit of claim 2, wherein the first filter circuit comprises a first current limiting resistor and a first filter capacitor electrically coupled in series between the audio input terminal and the amplification circuit.

4. The volume adjustment circuit of claim 2, wherein the adjustment circuit comprises a second current limiting resistor and a transistor, a base electrode of the transistor is configured for receiving the control signal, and is electrically coupled to the control circuit via the second current limiting resistor, an emitter electrode of the transistor is grounded, and a collector electrode of the transistor is electrically coupled to the audio input terminal or an output terminal of the first filter circuit.

5. The volume adjustment circuit of claim 4, wherein the control circuit comprising a voltage divider for performing a voltage division on the second audio signal to form the control signal.

6. The volume adjustment circuit of claim 5, wherein the voltage divider comprises a first voltage dividing resistor and a second voltage dividing resistor electrically coupled in series between the audio output terminal and ground.

7. The volume adjustment circuit of claim 6, wherein the voltage divider further comprises a diode, an anode of the diode is electrically coupled to a node between the first voltage dividing resistor and the second voltage dividing resistor, and a cathode of the diode is electrically coupled to the second current limiting resistor.

8. The volume adjustment circuit of claim 7, wherein the voltage divider further comprises a filter branch and a discharge branch electrically coupled between the cathode of the diode and ground.

9. The volume adjustment circuit of claim 2, wherein the amplification circuit further comprises a second filter circuit and an operational amplifier circuit, the second filter circuit is electrically coupled between the first filter circuit and the operational amplifier circuit, the operational amplifier circuit comprises an operational amplifier, a first bias resistor and a second bias resistor, an in-phase input of the operational amplifier is configured for receiving a reference voltage signal, a reversed-phase input of the operational amplifier is electrically coupled to the second filter circuit via the first bias resistor, and the second bias resistor is electrically coupled between the reversed-phase input of the operational amplifier and the audio output terminal.

10. The volume adjustment circuit of claim 9, wherein the second filter circuit comprises a second filter capacitor and a third filter capacitor are electrically coupled between the first filter circuit and the operational amplifier circuit, a node between the second filter capacitor and the third filter capacitor is eclectically coupled to audio output terminal via a resistor.

11. An electronic device, comprising:
a voltage adjustment circuit;
an audio source electrically coupled to an audio input terminal of the voltage adjustment circuit, the audio source being configured for providing an input audio signal to the voltage adjustment circuit; and
a speaker electrically coupled to an audio output terminal of the voltage adjustment circuit, the speaker being configured for transforming an output audio signal of the volume adjustment circuit into an audible signal;
wherein the volume adjustment circuit comprises:
an amplification circuit, configured for amplifying the audio signal to generate the output audio signal, and outputting the second audio signal to the speaker via the audio output terminal;
a control circuit electrically coupled to the audio output terminal, the control circuit being configured for generating a control signal based on the output audio signal; and
an adjustment circuit electrically coupled to the control circuit, the adjustment circuit being configured for adjusting an amplitude of the audio signal inputted to the amplification circuit based on the control circuit.

12. The electronic device of claim 11, wherein the volume adjustment circuit further comprises a first filter circuit electrically coupled between an audio input terminal and the amplification circuit, wherein the first filter circuit is configured for filtering out a direct current component from the input audio signal provided the audio input terminal, and output the filtered audio signal to the amplification circuit.

13. The electronic device of claim 12, wherein the first filter circuit comprises a first current limiting resistor and a first filter capacitor electrically coupled in series between the audio input terminal and the amplification circuit.

14. The electronic device of claim 12, wherein the adjustment circuit comprises a second current limiting resistor and a transistor, an base electrode of the transistor is configured for receiving the control signal, and is electrically coupled to the control circuit via the second current limiting resistor, an emitter electrode of the transistor is grounded, and a collector electrode of the transistor is electrically coupled to the audio input terminal or an output terminal of the first filter circuit.

15. The electronic device of claim 14, wherein the control circuit comprising a voltage divider for performing a voltage division on the output audio signal to form the control signal.

16. The electronic device of claim 15, wherein the voltage divider comprises a first voltage dividing resistor and a second voltage dividing resistor electrically coupled in series between the audio output terminal and ground.

17. The electronic device of claim 16, wherein the voltage divider further comprises a diode, an anode of the diode is electrically coupled to a node between the first voltage dividing resistor and the second voltage dividing resistor, and a cathode of the diode is electrically coupled to the second current limiting resistor.

18. The electronic device of claim 17, wherein the voltage divider further comprises a filter branch and a discharge branch electrically coupled between the cathode of the diode and the ground.

19. The electronic device of claim 12, wherein the amplification circuit further comprises a second filter circuit and an operational amplifier circuit, the second filter circuit is electrically coupled between the first filter circuit and the operational amplifier circuit, the operational amplifier circuit comprises an operational amplifier, a first bias resistor and a second bias resistor, an in-phase input of the operational amplifier is configured for receiving a reference voltage signal, an reversed-phase input of the operational amplifier is electrically coupled to the second filter circuit via the first bias resistor, and the second bias resistor is electrically coupled between the reversed-phase input of the operational amplifier and the audio output terminal.

20. The electronic device of claim 19, wherein the second filter circuit comprises a second filter capacitor and a third filter capacitor are electrically coupled between the first filter circuit and the operational amplifier circuit, an node between the second filter capacitor and the third filter capacitor is eclectically coupled to audio output terminal via a resistor.
